(19) United States
(12) Patent Application Publication
(10) Pub. No.: US 2012/0103410 A1
(43) Pub. Date: May 3, 2012

(54) CONDUCTIVE PASTE COMPOSITE

(75) Inventors: JIN GYEONG PARK, Seoul (KR); In Jae Lee, Seoul (KR); Soon Gil Kim, Seoul (KR); Jun Phill Eom, Seoul (KR)

(73) Assignee: LG INNOTEK CO., LTD., Seoul (KR)

(21) Appl. No.: 13/283,732

(22) Filed: Oct. 28, 2011

(30) Foreign Application Priority Data
Oct. 28, 2010 (KR) 10-2010-0106328

(51) Int. Cl. H01L 31/0224; H01B 1/02; H01B 1/00; B82Y 30/00

(52) U.S. Cl. 136/256; 252/500; 252/512; 252/514; 977/773

(57) ABSTRACT

Provided is a conductive paste composite. The conductive paste composite comprises first conductive powder having a first average grain size, and second conductive powder having a second average grain size.

### CROSS-REFERENCE TO RELATED APPLICATION

This application claims the benefit under 35 U.S.C. §119 of Korean Patent Application No. 10-2010-0106328, filed Oct. 28, 2010, which is hereby incorporated by reference in its entirety.

### BACKGROUND

The present disclosure relates to a conductive paste composite, and more particularly, to a conductive paste composite for forming an electrode or wire.

Electrodes or wires are disposed on devices such as display devices, photovoltaic cells, and mobile devices for charge transfer or power supply. Such electrodes or wires may be formed by printing, drying, and firing patterns with a conductive paste composite.

Thicker electrodes or wires have better electric conductivity owing to low surface resistance. When electrodes or wires are formed through a printing process using a conductive paste composite, printing may be performed two or more times to increase the thicknesses of the electrodes or wires. In this case, however, the process time may increase to lower the productivity, and it may be difficult to precisely align patterns while repeating printing operations. In addition, when a plurality of layers of a conductive paste composite are treated through a firing process, errors such as incomplete combustion, bubbles, and cracks may occur.

### BRIEF SUMMARY

Embodiments provide a paste composite that can be used to form an electrode or wire having a large aspect ratio through a simple process.

In one embodiment, a paste composite comprising a conductive powder, wherein the conductive powder: first conductive powder having a first average grain size; and second conductive powder having a second average grain size greater than the first average grain size.

The conductive powder may comprise 10 wt % to 90 wt % of the first conductive powder.

The second average grain size may be 1.5 times to 4.5 times the first average grain size.

The first average grain size may range from 20 nm to 40 nm, and the second average grain size may range from 60 nm to 90 nm.

The first and second conductive powders may comprise at least one of a metal and a conductive polymer material.

The metal may comprise at least one selected from the group consisting of silver, aluminum, gold, copper, and an alloy including any one thereof.

The conductive polymer material may comprise at least one of polypyrrole and polyaniline.

The paste composite may further comprise an organic vehicle and glass frit.

The paste composite may comprise 50 wt % to 90 wt % of the conductive powder.

The paste composite may be used to form an electrode or a wire.

The details of one or more embodiments are set forth in the accompanying drawings and the description below. Other features will be apparent from the description and drawings, and from the claims.

### BRIEF DESCRIPTION OF THE DRAWINGS

FIG. 1 is a sectional view illustrating a photovoltaic cell according to an embodiment.

FIG. 2 is a graph showing results of x-ray diffraction analysis performed on first silver powder and second silver powder used in Example 1.

### DETAILED DESCRIPTION

In the description of embodiments, it will be understood that when a layer (or film), region, pattern or structure is referred to as being ‘on’ or ‘under’ another layer (or film), region, pad or pattern, the terminology of ‘on’ and ‘under’ includes both the meanings of ‘directly’ and ‘indirectly’. Further, the reference about ‘on’ and ‘under’ each layer will be made on the basis of drawings.

In the drawings, the dimensions and size of each layer (or film), region, pattern or structure may be exaggerated, omitted, or schematically illustrated for convenience in description and clarity.

Hereinafter, a conductive paste composite (also referred to as ‘paste composite’) will be described in detail according to embodiments.

The paste composite of the embodiment may include conductive powder, an organic vehicle, and glass frit. In addition, the paste composite may include other additives for improving properties.

The conductive powder may include material such as a metal and a conductive polymer material. Examples of the metal include silver, aluminum, gold, copper, and an alloy including one of the listed metals. Examples of the conductive include polypyrrole and polyaniline.

The conductive powder of the embodiment may include conductive powder having different average grain sizes. For example, the conductive powder may include: first conductive powder having a first average grain size; and second conductive powder having a second average grain size.

The second average grain size may be greater than the first average grain size.

According to the current embodiment, owing to the first conductive powder and the second conductive powder having different average grain sizes, a firing process may proceed step by step at different temperatures. That is, since a sintering temperature for conductive powder having a relatively large average grain size is higher than a sintering temperature for conductive powder having a relatively smaller average grain size, when the first conductive powder having a relatively small average grain size is sintered, the second conductive powder having a relatively large average grain size may not be sintered and thus function as a support.

Therefore, electrodes or wires formed through printing, drying, and firing processes using the paste composite of the embodiment may have a large aspect ratio.
In the case of using conductive powder having a single average grain size in the related art, since a firing process is performed at a time at a certain temperature, wires or electrodes may collapse due to meltdown and thus it may be difficult to form wires or electrodes having a large aspect ratio.

However, according to the embodiment, electrodes or wires having a large aspect ratio can be formed so that electric conductive of the electrodes or wires can be improved owing to low surface resistance. In addition, it is not necessary to repeat printing if the paste composite of the embodiment. Therefore, processes can be simplified, and thus productivity can be improved. In addition, since electrodes or wires can be formed in a single layer through one printing process, surface defects and alignment errors can be minimized.

The conductive powder of the embodiment may include 10 wt % to 90 wt % of the first conductive power and 10 wt % to 90 wt % of the second conductive powder. That is, for forming electrodes or wires having a large aspect ratio at different firing temperatures, each of the first and second conductive powder is included in the conductive powder at a content of 10 wt % or higher.

The second average grain size may 1.5 to 4.5 times the first average grain size. For example, the second average grain size may 2 to 4.5 times the first average grain size.

If the second average grain size is not greater than 1.5 times the first average grain size, since a firing temperature difference is not large, an aspect ratio may not be sufficiently large. For example, if the second average grain size is twice the first average grain size, a firing temperature difference of about 100° C. may be obtained. In addition, if the second average grain size is greater than 4.5 times the first average grain size, the conductive powder may not be well sintered, and thus the electric conductivity of electrodes or wires may be reduced.

For example, the first average grain size may be 20 nm to 40 nm, and the second average grain size may be 60 nm to 90 nm. A high aspect ratio and electric conductivity may be obtained in the above range.

The conductive powder may include spherical particles. However, the current embodiment is not limited thereto. For example, conductive powder may include plate-shaped particles, dome-shaped particles, or flake-shaped particles.

The average grain diameter of the conductive powder may range from 1 μm to 10 μm. If the average grain diameter is smaller than 1 μm, an organic substance may not easily permeate the conductive powder due to narrow gaps between particles of the conductive powder, and thus diffusion may not be smooth. On the other hand, if the average grain diameter is greater than 10 μm, the density of the conductive powder is lowered due to large gaps between particles of the conductive powder, and thus the resistance of the conductive powder may increase.

The organic vehicle may include a solvent and a binder solved in the solvent. The organic may further include a material such as a defoamer and a dispersing agent. The solvent may be an organic solvent such as terpineol and carbitol. The binder may be a resin such as acrylic resins, cellulose resins, and alkyd resins. However, the current embodiment is not limited thereto. That is, various organic vehicles may be used.

The organic vehicle may further include a material such as a thixotropic agent and a leveling agent. The thixotropic agent may include a polymer/organic substance such as ureas, amides, and urethanes. Alternatively, the thiotropic agent may include inorganic silica.

The glass frit may include a material such as PbO—SiO₂, PbO—SiO₂—B₂O₃, ZnO—SiO₂, ZnO—B₂O₃—SiO₂, and Bi₂O₃—B₂O₃—ZbO—SiO₂.

For example, the paste composite may include 50 wt % to 90 wt % of the conductive powder, 10 wt % to 50 wt % of the organic vehicle, and 1 wt % to 20 wt % of the glass frit.

If the content of the conductive powder is greater than 90 wt %, it may be difficult to prepare the composite in the form of paste. If the content of the conductive powder is less than 50 wt %, the electric conductivity of manufactured electrodes or wires may be low due to the insufficient content of the conductive powder.

If the content of the organic vehicle is greater than 50 wt %, the electric conductivity of manufactured electrodes or wires may be low. If the content of the organic vehicle is less than 10 wt %, electrodes or wires may not be firmly bonded to a substrate.

When the content of the glass frit ranges from 1 wt % to 20 wt %, characteristics such as bonding and firing characteristics of the paste composite may be improved.

The above-described paste composite may be prepared by the following method.

A binder is solved in a solvent is pre-mixed to prepare an organic vehicle. Next, conductive powder and additives are added to the organic vehicle and the mixture is left for 1 to 12 hours (aging). At this time, glass frit may be also added. The aged mixture is mechanically mixed and dispersed by using a three-roll mill. Then, the mixture is prepared as a paste composite through filtering and defoaming processes. The above-described method is an exemplary example. The current embodiment is not limited thereto.

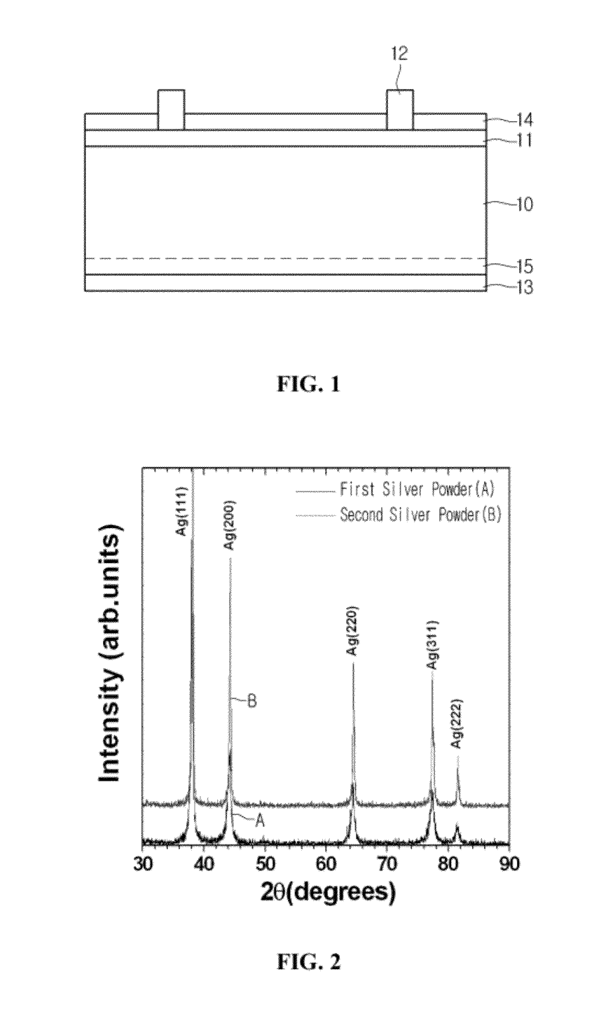

The paste composite of the embodiment may be used for forming electrodes or wires of display devices such as plasma display panels and liquid crystal display panels, electrodes or wires of touch panels of mobile devices, or electrodes or wires of photovoltaic cells. An explanation will now be given of an exemplary example in which the paste composite of the embodiment is used to form electrodes of a photovoltaic cell. FIG. 1 is a sectional view illustrating a photovoltaic cell according to an embodiment.

Referring to FIG. 1, the photovoltaic cell includes: a p-type silicon substrate 10 including an n-type semiconductor part 11 on a front side thereof; a front electrode 12 electrically connected to the n-type semiconductor part 11; and a back electrode 13 electrically connected to the p-type silicon substrate 10. An anti-reflection layer 14 may be disposed on the top side of the n-type semiconductor part 11 except for the front electrode 12. A back surface field (BSF) layer 15 may be disposed on the back side of the p-type silicon substrate 10 where the back electrode is formed.

The paste composite of the embodiment may be used to form the front electrode 12 or the back electrode 13. For example, the paste composite of the embodiment may be applied to the silicon substrate 10 by a printing method, and then the paste composite may be dried and fired to form the front electrode 12 and the back electrode 13. For example, when the paste composite is used to form the front electrode 12, the conductive powder of the paste composite may be silver powder, and when the paste composite is used to form the back electrode 13, the conductive powder of the paste composite may be aluminum powder.

The paste composite may be dried at 80° C. to 200° C. for 1 to 30 minutes and then fired at 700° C. to 900° C. through a rapid heat treatment process. However, the scope of the present disclosure is not limited to the temperature range and time period.

Hereinafter, more detailed descriptions will be given on examples. The following examples are not limiting examples. That is, the scope and spirit of the present disclosure are not limited thereto.

### Example 1

A binder was solved in a solvent to prepare an organic vehicle. A blend of diethylene glycol monobutyl ether acetate and α-terpineol was used as the solvent, and a binder illustrating ethyl cellulose was used as the binder. Silver powder and glass frit were added to the organic vehicle and were mixed. The mixture was aged for 12 hours and secondarily mixed and dispersed using a three-roll mill. Then, the mixture was prepared as a paste composite through filtering and defoaming processes.

The paste composite included 15 wt % of the organic vehicle, 80 wt % of the silver powder, and 5 wt % of the glass frit. The silver powder included: 90 wt % of first silver powder having a grain size in the range from 25 nm to 35 nm; and 10 wt % of second silver powder having a grain size in the range from 65 nm to 75 nm. FIG. 2 shows results of x-ray diffraction analysis performed on the first silver powder and the second silver powder.

The paste composite was applied to a substrate by a screen printing method under the following conditions: line width of 150 μm, thickness of 70 μm, and bias angle of 22.5°. Then, the paste composite was dried at 200° C. for 2 minutes. Thereafter, the paste composite was fired at 700° C. for two minutes. Eight electrode samples were made in the same manner.

### Example 2

Eight electrode samples were made in the same manner as that of Example 1 except for silver powder included 80 wt % of first silver powder and 20 wt % of second silver powder.

### Example 3

Eight electrode samples were made in the same manner as that of Example 1 except for silver powder included 70 wt % of first silver powder and 30 wt % of second silver powder.

### Comparative Example

Eight electrode samples were made in the same manner as that of Example 1 except for silver powder having an average grain size in the range from 25 nm to 35 nm was used.

Table 1 blow shows average line widths, average heights, and average aspect ratios of the electrode samples of Examples 1 to 3 and Comparative example.

TABLE 1

| | Average line width | Average height | |
|---|---|---|---|
| | [μm] | [μm] | Aspect ratio |
| Example 1 | 179.2663 | 37.04 | 0.206977 |
| Example 2 | 164.4738 | 39.7425 | 0.242272 |
| Example 3 | 164.3463 | 40.07375 | 0.244268 |
| Comparative | 169.495 | 32.61875 | 0.192858 |
| Example | | | |

Referring to Table 1, the average aspect ratios of the electrode samples of Examples 1 to 3 are 0.206977, 0.242272, and 0.244268, respectively, which are greater than 0.192858: the average aspect ratio of the electrode samples of Comparative example. The aspect ratio increases in the order of Examples 1, 2, and 3. That is, as the content of the second silver powder increases (10%, 20%, and 30%), the aspect ratio increases. This may be because the second silver powder functions as a support structure at the sintering temperature of the first silver powder.

According to the embodiment, since the conductive paste composite includes conductive powders having different average grain sizes, the conductive paste composite can be fired step by step at different temperatures. That is, since a sintering temperature for conductive powder having a relatively large average grain size is higher than a sintering temperature for conductive powder having a relatively smaller average grain size, when the conductive powder having a relatively small average grain size is sintered, the conductive powder having a relatively large average grain size may not be sintered and thus function as support structures. Therefore, electrodes or wires formed using the conductive paste composite can have a large aspect ratio.

Thus, the surface resistance of the electrodes or wires can be low, and the electric conductivity of the electrodes or wires can be high. In addition, it is not necessary to repeat printing if the conductive paste composite of the embodiment is used. Therefore, processes can be simplified, and thus productivity can be improved. Therefore, electrodes or wires can be formed in a single layer through one printing process, and thus surface defects and alignment errors can be minimized.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A paste composite comprising a conductive powder,
wherein the conductive powder:
first conductive powder having a first average grain size; and
second conductive powder having a second average grain size greater than the first average grain size.

2. The paste composite according to claim 1, wherein the conductive powder comprises 10 wt % to 90 wt % of the first conductive powder.

3. The paste composite according to claim 1, wherein the conductive powder comprises 10 wt % to 90 wt % of the second conductive powder.

4. The paste composite according to claim 1, wherein the second average grain size is 1.5 times to 4.5 times the first average grain size.

5. The paste composite according to claim 1, wherein the second average grain size is 2.0 times to 4.5 times the first average grain size.

6. The paste composite according to claim 1, wherein the first average grain size ranges from 20 nm to 40 nm, and the second average grain size ranges from 60 nm to 90 nm.

7. The paste composite according to claim 1, wherein the first and second conductive powders comprise at least one of a metal and a conductive polymer material.

8. The paste composite according to claim 7, wherein the metal comprises at least one selected from the group consisting of silver, aluminum, gold, copper, and an alloy including any one thereof.

9. The paste composite according to claim 7, wherein the conductive polymer material comprises at least one of polypyrrole and polyaniline.

10. The paste composite according to claim 1, further comprising an organic vehicle and glass frit.

11. The paste composite according to claim 1, wherein the paste composite comprises 50 wt % to 90 wt % of the conductive powder.

12. The paste composite according to claim 1, wherein the paste composite is used to form an electrode or a wire.

13. A photovoltaic cell comprising an electrode formed of the paste composite of claim 1.
